(19) United States
(12) Patent Application Publication
(10) Pub. No.: US 2026/0214943 A1
(43) Pub. Date: Jul. 23, 2026

(54) SEMICONDUCTOR STRUCTURE AND METHOD FOR MANUFACTURING THE SAME

(71) Applicant: TAIWAN SEMICONDUCTOR MANUFACTURING COMPANY LTD., HSINCHU (TW)

(72) Inventors: YUN-FENG KAO, NEW TAIPEI CITY (TW); KATHERINE H. CHIANG, NEW TAIPEI CITY (TW); MING-YEN CHUANG, HSINCHU CITY (TW); CHIA YU LING, HSINCHU CITY (TW)

(21) Appl. No.: 19/033,665

(22) Filed: Jan. 22, 2025

(51) Int. Cl. H10D 30/67; H10B 12/00; H10D 30/01

(52) U.S. Cl. CPC H10D 30/6739; H10B 12/05; H10B 12/315; H10D 30/0316; H10D 30/6732; H10D 30/6755

(57) ABSTRACT

A semiconductor structure is provided. The semiconductor structure includes an insulating layer, a gate structure, a dielectric layer, a channel layer, a source structure, and a drain structure. The gate structure is embedded in the insulating layer. The gate structure includes a gate material portion having two opposite sides and a first oxide portion and a second oxide portion adjacent to the gate material portion at the two opposite sides of the gate material portion. The dielectric layer is over the insulating layer. The channel layer is over the dielectric layer. The source structure and the drain structure are directly over the first oxide portion and the second oxide portion of the gate structure, respectively. A method for manufacturing the semiconductor structure is also provided.

### BACKGROUND

The gate voltage in a transistor can be influenced by several factors that affect its values and switching efficiency. For instance, the threshold voltage of the transistor may determine the minimum gate voltage required to turn the device on; the gate capacitance can affect how quickly the gate can charge and discharge, influencing switching speed; and the drive strength of the gate driver may impact the ability to rapidly change the gate voltage. Additionally, temperature variations can alter the electrical characteristics of the transistor and its performance as well.

### BRIEF DESCRIPTION OF THE DRAWINGS

Aspects of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 illustrates a cross-sectional view of a semiconductor structure according to some embodiments of the present disclosure.

FIG. 2 illustrates a cross-sectional view of a semiconductor structure according to some embodiments of the present disclosure.

FIG. 3A illustrates a cross-sectional view of a semiconductor structure according to some embodiments of the present disclosure.

FIG. 3B illustrates a cross-sectional view of a semiconductor structure according to some embodiments of the present disclosure.

FIG. 4A illustrates a top view of a portion of a semiconductor structure according to some embodiments of the present disclosure.

FIG. 4B illustrates a top view of a portion of a semiconductor structure according to some embodiments of the present disclosure.

FIG. 4C illustrates a top view of a portion of a semiconductor structure according to some embodiments of the present disclosure.

FIG. 4D illustrates a top view of a portion of a semiconductor structure according to some embodiments of the present disclosure.

FIG. 5A illustrates a cross-sectional view of a semiconductor structure according to some embodiments of the present disclosure.

FIG. 5B illustrates a cross-sectional view of a semiconductor structure according to some embodiments of the present disclosure.

FIG. 5C illustrates a cross-sectional view of a semiconductor structure according to some embodiments of the present disclosure.

FIG. 5D illustrates a cross-sectional view of a semiconductor structure according to some embodiments of the present disclosure.

FIG. 6A illustrates a cross-sectional view of a semiconductor structure according to some embodiments of the present disclosure.

FIG. 6B illustrates a cross-sectional view of a semiconductor structure according to some embodiments of the present disclosure.

FIG. 6C illustrates a cross-sectional view of a semiconductor structure according to some embodiments of the present disclosure.

FIG. 7 illustrates a cross-sectional view of a semiconductor structure according to some embodiments of the present disclosure.

FIG. 8 illustrates a flow diagram illustrating a method for manufacturing a semiconductor structure according to some embodiments of the present disclosure.

FIGS. 9A-9D illustrate cross-sectional views of a process in manufacturing a gate structure of a semiconductor structure according to some embodiments of the present disclosure.

FIGS. 10A and 10B illustrate cross-sectional views of a process in manufacturing a oxide portion in a gate structure of a semiconductor structure according to some embodiments of the present disclosure.

FIGS. 11A-11 E illustrate cross-sectional views of a process in manufacturing a source structure and a drain structure of a semiconductor structure according to some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” "on" and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as "first", "second" and "third" describe various elements, components, regions, layers and/or sections, these elements, components, regions, layers and/or sections should not be limited by these terms. These terms may be only used to distinguish one element, component, region, layer, or section from another. The terms such as "first", "second", and "third" when used herein do not imply a sequence or order unless clearly indicated by the context.

The subthreshold swing (SS) is one of the parameters of a semiconductor device, it may be concerned in developing semiconductor devices such as MOSFETs. Generally, it measures how efficiently a transistor can switch from the “OFF” state to the “ON” state in response to a change in gate voltage. That is, it refers to whether the transistor is effectively blocking or allowing current flow between the source and drain terminals, while these states are controlled by the gate voltage.

In the OFF state, the gate voltage (V_{G}) is below the threshold voltage (Vₜₕ). At this point, the transistor operates in the subthreshold region that is usually known as the weak inversion region. Moreover, when the transistor is in the OFF state, the channel between the source and drain is not fully formed, meaning there are very few charge carriers (e.g., electrons or holes) available for conduction and therefore the current is low. Such low current is a kind of leakage current that arises due to the weak inversion effect, where a small number of carriers still move across the channel due to diffusion. The OFF state is related to the aspect of minimizing power consumption in standby modes, as excessive leakage current can increase static power dissipation.

In contrast, in the ON state, the gate voltage (V_{G}) exceeds the threshold voltage (Vₜₕ), and the transistor enters the strong inversion region. In some typical cases, when the transistor is in the ON state, the conductive channel forms and allowing current flow from the source to the drain, and the drain current in this state increases rapidly with the gate voltage. The ON state enables the device to conduct efficiently and perform switching or amplification functions.

As aforementioned, the subthreshold swing describes how efficiently the transistor transitions from the OFF state (e.g., low current) to the ON state (e.g., high current) in response to changes in gate voltage. Typically, the subthreshold swing is defined as the amount of gate voltage required to increase the drain current by one order of magnitude (i.e., a factor of 10) in the subthreshold region. It can be expressed in millivolts per decade (mV/dec). In some cases, a smaller subthreshold swing value indicates a steeper transition from the OFF state to the ON state, meaning the transistor can switch more efficiently with smaller changes in gate voltage. This is desirable for low-power and high-performance applications. Generally, the minimum theoretical subthreshold swing value at room temperature is approximately 60 mV/dec, determined by the thermal voltage. However, most devices often have higher subthreshold swing values due to non-idealities like interface traps or parasitic capacitance.

In the field of application, a lower subthreshold swing value may allow the transistor to achieve a strong ON state with a lower gate voltage, reducing power consumption during operation. A lower subthreshold may also help maintain a low OFF-state leakage current, hence minimizing standby power dissipation. Also, since a smaller subthreshold swing value indicates a steeper transition from the OFF state to the ON state, such steeper subthreshold swing value may improve the speed of digital circuits and enable higher operating frequencies due to faster transitions between OFF and ON states.

In some comparative embodiments, a semiconductor structure may include a gate structure covered by a dielectric layer including high-k dielectric material (e.g., high-k dielectric layer) and a channel layer over the dielectric layer. Generally, the subthreshold swing value is proportional to the ratio value of the parasitic capacitance (hereinafter “capacitance”) in the OFF state (i.e., C_{OFF}) and the capacitance in the ON state (i.e., C_{ON}), i.e., the subthreshold swing value is proportional to C_{OFF}/C_{ON}. In the comparative embodiment, the capacitance in the ON state (C_{ON}) is approximately equal to the capacitance of the high-k dielectric layer (i.e., C_{HK}), while the capacitance in the OFF state (C_{OFF}) is equal to the equivalent capacitance of the high-k dielectric layer (C_{HK}) and the channel layer (i.e., C_{Channel}). Because the high-k dielectric layer and the channel layer are in contact with each other, these “capacitors” are effectively connected in series. Therefore, the equivalent capacitance (C_{eq}) thereof can be calculated using the formula: 1/C_{eq} = 1/C_{Channel} + 1/C_{HK}, and C_{eq} is equal to C_{OFF}.

Accordingly, to reduce the subthreshold swing value closer to the minimum theoretical limit at room temperature, lowering the capacitance in the OFF state (C_{OFF}) can be considered. Hence, in some embodiments of the present disclosure, an additional “capacitor” can be introduced into the semiconductor structure. For instance, since the equivalent capacitance of multiple capacitors connected in series is calculated as the reciprocal of the sum of the reciprocals of their individual capacitances, adding a capacitor in series can effectively reduce the overall capacitance compared to the original capacitance of each individual capacitor. Hence, in the aspect of connecting more capacitors in series, the C_{OFF} can be reduced.

In some embodiments of the present disclosure, other than the capacitance of the high-k dielectric layer (C_{HK}) and the capacitance of the channel layer (C_{Channel}), an additional oxide structure can be introduced into the semiconductor structure that connected with the high-k dielectric layer and the channel layer in series in the aspect of capacitance, and therefore the equivalent capacitance (C_{eq}) can be further reduced.

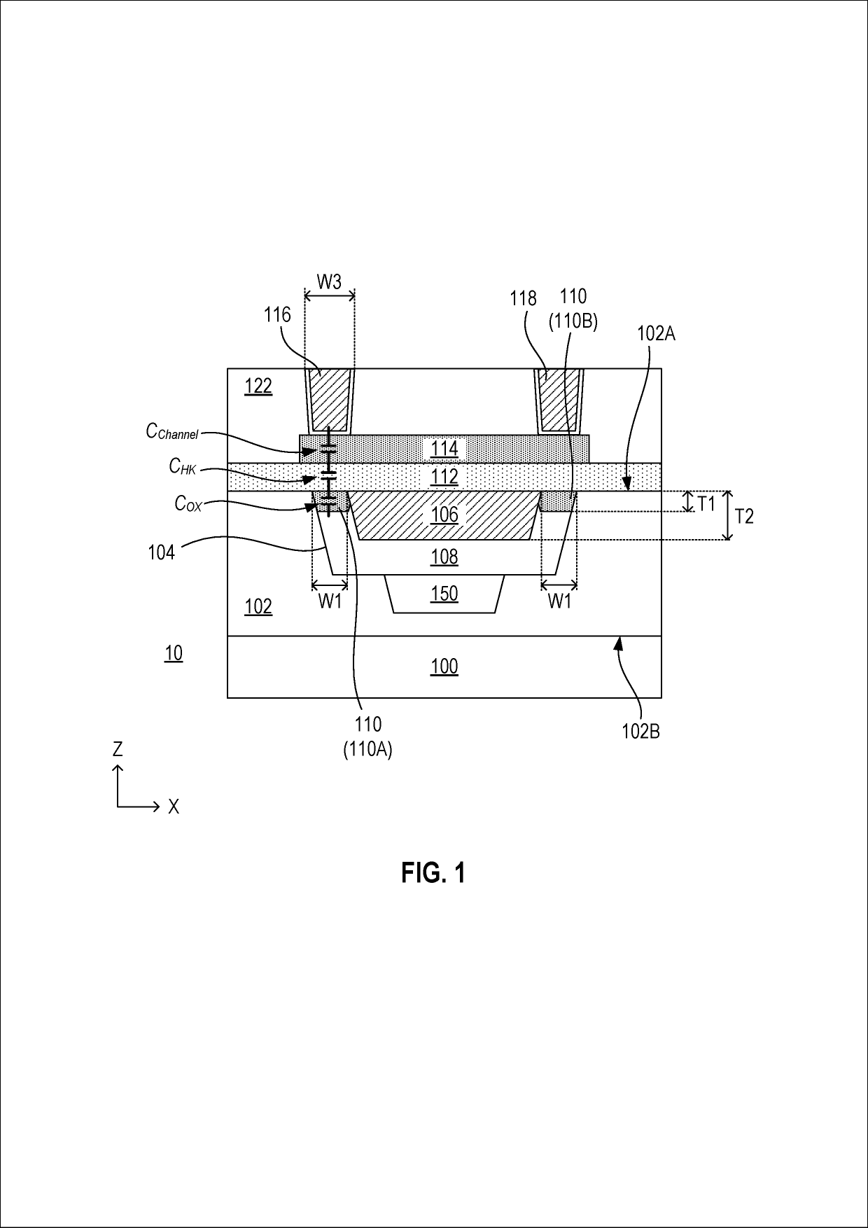

Referring to FIG. 1, which illustrates a semiconductor structure 10 according to some embodiments of the present disclosure. As shown in the figure, the semiconductor structure 10 includes an insulation layer 102 formed over a substrate 100. In some embodiments, the substrate 100 may include layers, structures, and/or components formed through a back-end-of-line (BEOL) process. For example, the substrate 100 may contain inter-metal dielectric (IMD) layers, vias, wiring layers, active components (e.g., transistors), and/or passive components (e.g., capacitors). In alternative embodiments, the substrate 100 may include layers, structures, and/or components formed through a front-end-of-line (FEOL) process. For instance, the substrate 100 may include a device layer formed on a semiconductor substrate. The device layer may consist of a wide variety of devices and interlayer dielectric (ILD) layers covering these devices.

In some embodiments, said devices in the device layer may include active components, passive components, or a combination of both. In other embodiments, the devices may consist of integrated circuit devices such as transistors, capacitors, resistors, diodes, photodiodes, and fuse devices. In one embodiment, the device layer may include a gate structure, source and drain regions, and isolation structures, such as shallow trench isolation (STI) structures. Within the device layer, various N-type metal-oxide-semiconductor (NMOS) and/or P-type metal-oxide-semiconductor (PMOS) devices, such as transistors or memory elements, may be formed and interconnected to perform one or more functions. Other devices, such as capacitors, resistors, diodes, photodiodes, fuses, and similar components, may also be formed over the semiconductor substrate. The functions of these devices may include memory, processing, sensing, amplification, power distribution, input/output circuitry, or similar operations.

Said semiconductor substrate may be a bulk semiconductor, a semiconductor-on-insulator (SOI) substrate, or another type of substrate made of semiconductor material. It may be doped (e.g., with a p-type or n-type dopant) or undoped. The substrate 100 also may be a wafer, such as a silicon wafer, or an SOI substrate typically consists of a semiconductor layer formed on an insulator layer, such as a buried oxide (BOX) layer, silicon oxide layer, or similar material. The substrate 100 also may be a substrate made of glass.

In some embodiments, the insulation layer 102 includes a dielectric material such as silicon oxide, silicon nitride, silicon oxynitride, a spin-on dielectric material, or a low-k dielectric material (e.g., a material with a dielectric constant generally lower than about 3.9). Additionally, the insulation layer 102 may include undoped silicate glass, doped silicate glass, organosilicate glass, or a porous dielectric material. In some embodiments, the thickness of the insulation layer 102 may range from about 20 nm to about 300 nm, although smaller or larger thicknesses may also be used.

In some embodiments, the insulation layer 102 has a first side 102A and a second side 102B opposite to the first side 102A. In some embodiments, the second side 102B is facing the substrate 100, while a gate structure 104 is embedded at the first side 102A of the insulating layer 102. In some embodiments, the gate structure 104 is referred to as a bottom gate structure because it is positioned beneath a channel layer (described later). In some embodiments, the gate structure 104 includes a gate material portion 106 that extends downward from the first side 102A of the insulating layer 102. The gate material portion 106 may serve as a gate electrode made of a conductive material. For example, the gate material portion 106 may include metallic materials such as silver (Ag), aluminum (A1), copper (Cu), tungsten (W), nickel (Ni), other suitable metals, their alloys, or combinations thereof. Additionally, the gate material portion 106 may include metal compounds such as titanium nitride (TiN), tantalum nitride (TaN), metal silicide, other suitable materials, or combinations thereof. In some embodiments, the gate material portion 106 may also be a non-metal electrode composed of polycrystalline silicon or doped silicon.

In some embodiments, the gate structure 104 further includes a barrier layer 108 laterally surrounding the gate material portion 106. The barrier layer 108 includes oxide semiconductor material with high carrier concentration and has a high etch selectivity to the material of the gate material portion 106. In some embodiments, the barrier layer 108 may be used to reduce or minimize diffusion of the material of the gate material portion 106 into the insulation layer 102.

FIG. 1 illustrates the embodiment that the barrier layer 108 is performed as a gate barrier and can be made of an oxide semiconductor material. For example, the barrier layer 108 may include indium gallium zinc oxide (InGaZnO, IGZO), tungsten-doped indium oxide (InWO), indium zinc oxide (InZnO), indium tin oxide (InSnO), zinc oxide (ZnO), gallium oxide (GaOₓ), indium oxide (InOₓ), aluminum zinc oxide (AZO), or combinations thereof. In some embodiments the barrier layer 108 is in contact with a sidewall of the gate material portion 106 and a bottom of the gate material portion 106. In some embodiments, a profile of the barrier layer 108 is at least conformal to a lower sidewall and the bottom of the gate material portion 106.

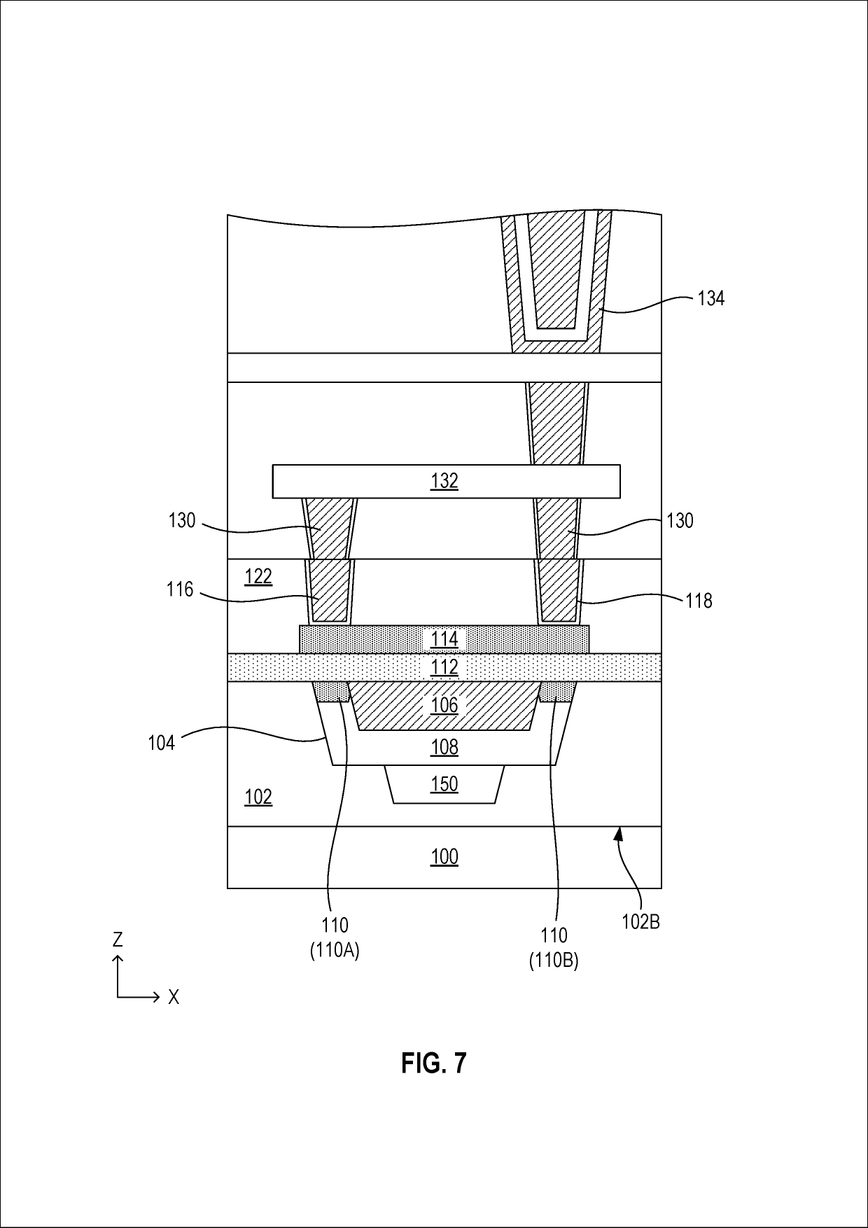

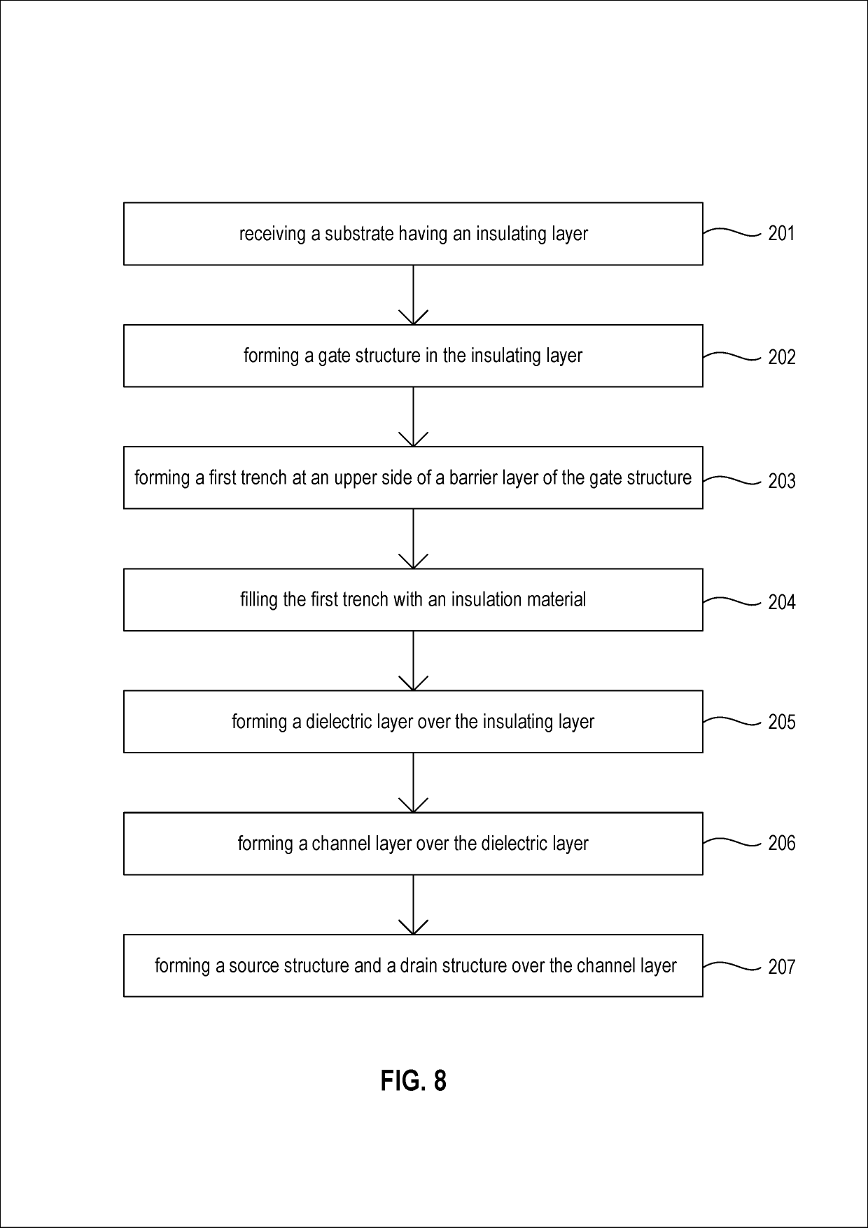

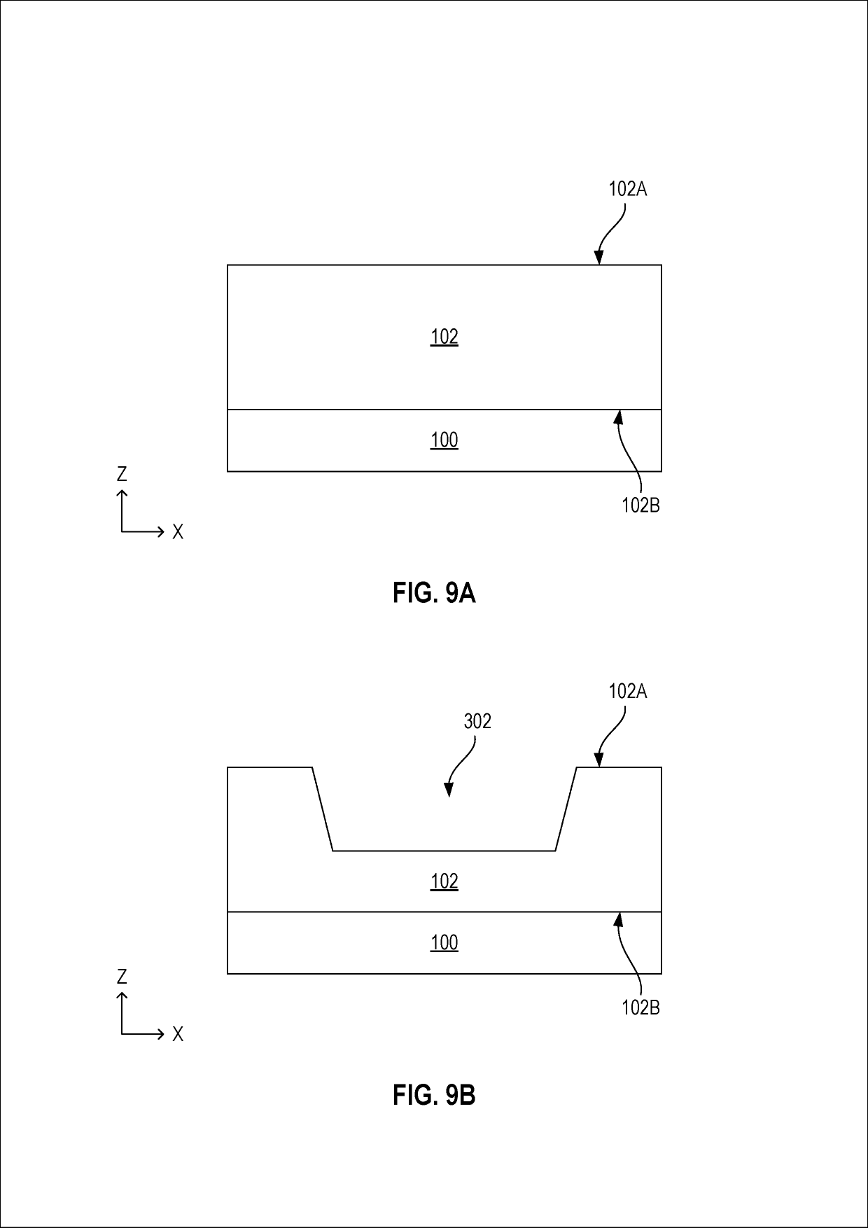

In some embodiments, the gate structure 104 further includes a liner layer 109 (shown in FIGS. 6A to 6C) that can be a single layer or a combination of plurality of sublayers that includes adhesion liners (e.g., liners that are included to promote adhesion between the gate material portion 106 and the insulation layer 102) and/or another type of liner layers. For simplification purposes, the liner layer 109 could be a portion of the gate structure 104 (even though the materials thereof are different) and waived from illustrated in some of the figures.

In some embodiments, the gate structure 104 further includes an insulation portion such as an oxide portion 110 embedded in the barrier layer 108 at the first side 102A of the insulating layer 102. In some embodiments, a material of the oxide portion 110 may include SiO₂, AlOₓ, or other dielectric with low-k value (e.g., a material with a dielectric constant generally lower than about 3.9). As shown in FIG. 1, in some embodiments, the upper surface of the oxide portion 110 in the gate structure 104 is coplanar with the upper surface of the gate material portion 106. In some embodiments, a thickness T1 of the oxide portion 110 is in a range from about 0.5 nm to about 10 nm. The thickness T1 of the oxide portion 110 is less than a thickness T2 of the gate material portion 106. The oxide portion 110 is a structure that may provide (parasitic) capacitance and can be connected in series with other structures to reduce the equivalent capacitance (described later). The thickness T1 of the oxide portion 110 is related to its capacitance (C OX), which can affect both the equivalent capacitance and the subthreshold swing value of the semiconductor structure. In some embodiments, a width W1 of the oxide portion 110 is in a range from about 10 nm to about 100 nm. Compared to the thickness T1, the width W1 has less influence on the capacitance (C OX) of the oxide portion 110 but is related to the size of the gate structure 104.

In the embodiment shown in FIG. 1, the oxide portion 110 is substantially over the two upper ends of the barrier layer 108 from the cross-sectional view perspective. In such embodiments, a top surface of the barrier layer 108 is substantially lower than the upper surface of the gate material portion 106. This is one of the circumstances that the profile of the barrier layer 108 is conformal to the lower sidewall and the bottom of the gate material portion 106, since the upper sidewall can be in contact with and be surrounded by the oxide portion 110.

In some applications, the semiconductor structure 10 may further include a conductive structure 150 in the insulating layer 102 below and/or under the gate structure 104. For instance, the conductive structure 150 can be a word line conductive structure configured to selectively provide a voltage or current to the gate structure 104; the conductive structure 150 can also be an access line conductive structure, a select line conductive structure, an address line conductive structure, and/or a row line conductive structure, in different examples. In some embodiments, the conductive structure 150 may include a via, a metal line, a metallization layer, and/or another type of conductive structure. The conductive structure 150 may include one or more conductive materials, such as one or more metals, one or more metal alloys, and/or one or more other types of conductive materials. Examples include copper (Cu), cobalt (Co), ruthenium (Ru), titanium (Ti), tungsten (W), gold (Au), and/or silver (Ag), among other examples.

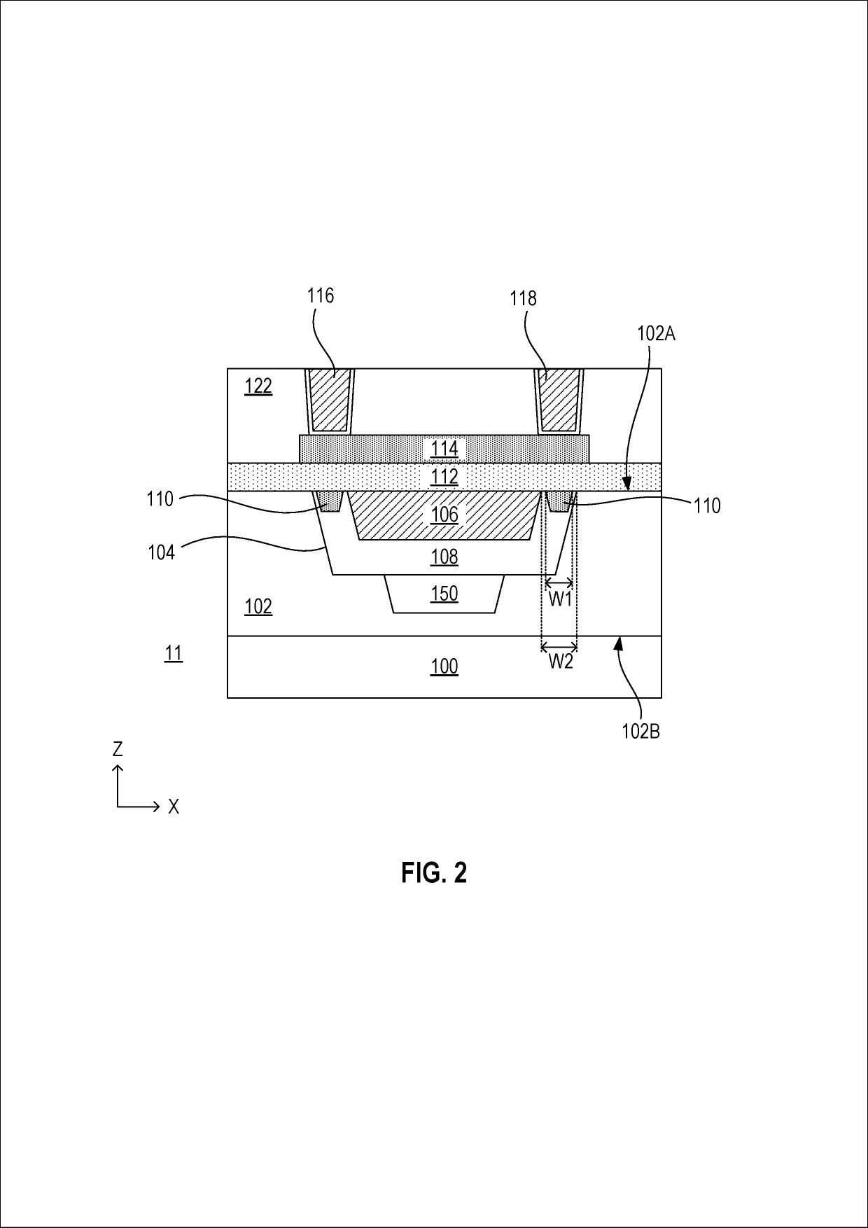

The barrier layer 108 in FIG. 1 is substantially free from higher than the oxide portion 110. Alternatively, as a semiconductor structure 11 illustrated in FIG. 2, in other embodiments, a top surface of the barrier layer 108 is substantially coplanar with the upper surface of the gate material portion 106. As shown in FIG. 2, a width W2 of the barrier layer 108 may be greater than the width W1 of the oxide portion 110 (e.g., the widths at the surfaces coplanar with the upper surface of the insulating layer 102), and therefore the oxide portion 110 is laterally surrounded by the barrier layer 108. For instance, two sidewalls of the oxide portion 110 are in contact with the barrier layer 108 from the cross-sectional view perspective.

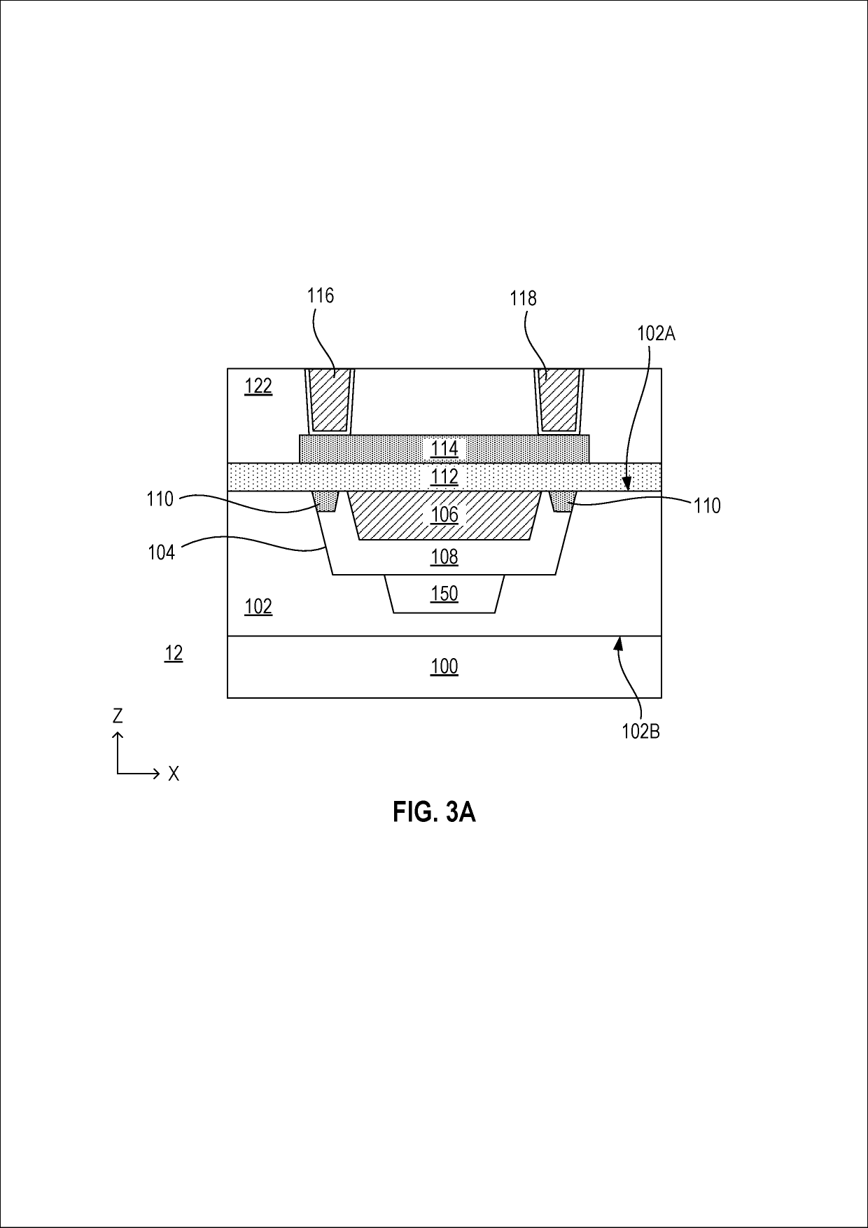

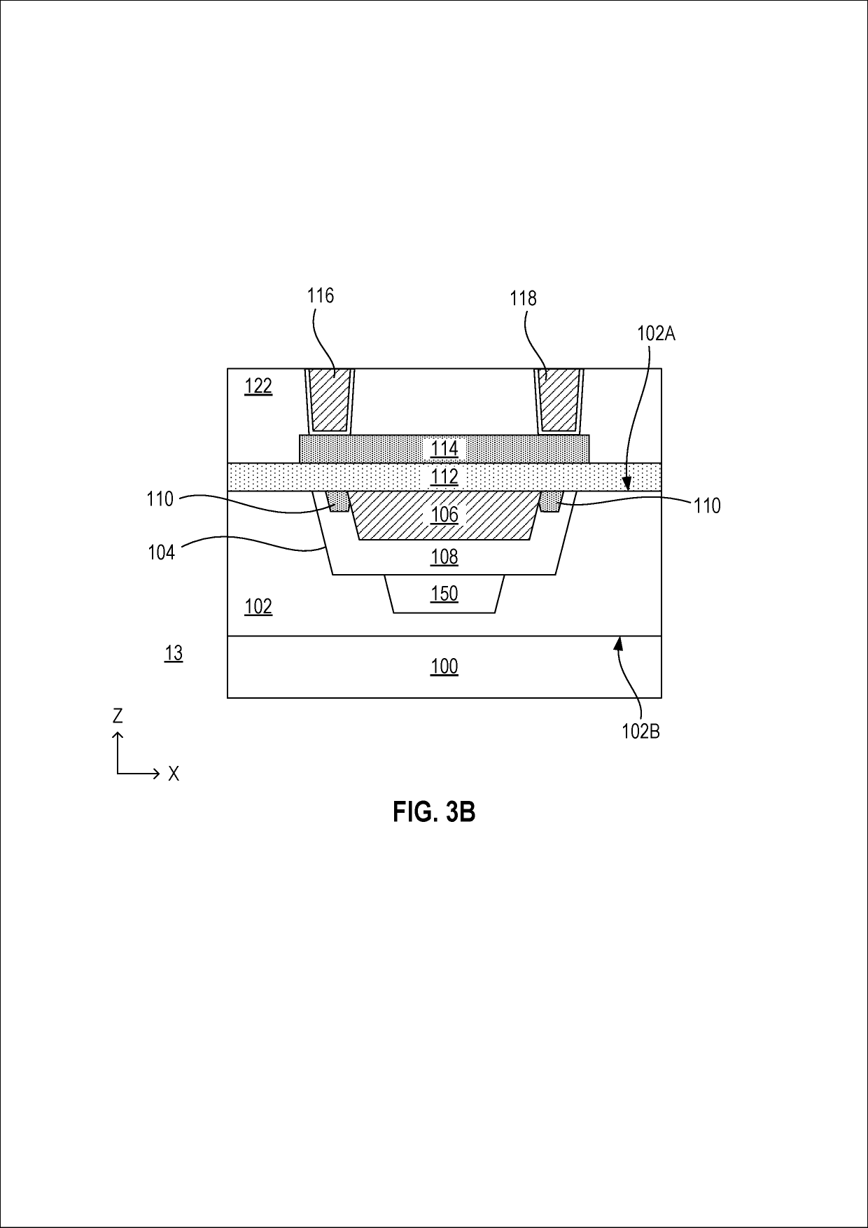

In some embodiments, due to the tapered profile of the sidewalls of the gate material portion 106, the barrier layer 108, and/or the oxide portion 110, the position of the oxide portion 110 may have a shift among different embodiments. For example, as a semiconductor structure 12 illustrated in FIG. 3A, the oxide portion 110 may in contact with the barrier layer 108 by one (lateral) side of the oxide portion 110. In some embodiments, as a semiconductor structure 13 shown in FIG. 3B, the oxide portion 110 may in contact with the gate material portion 106 by a portion of one (lateral) side of the oxide portion 110.

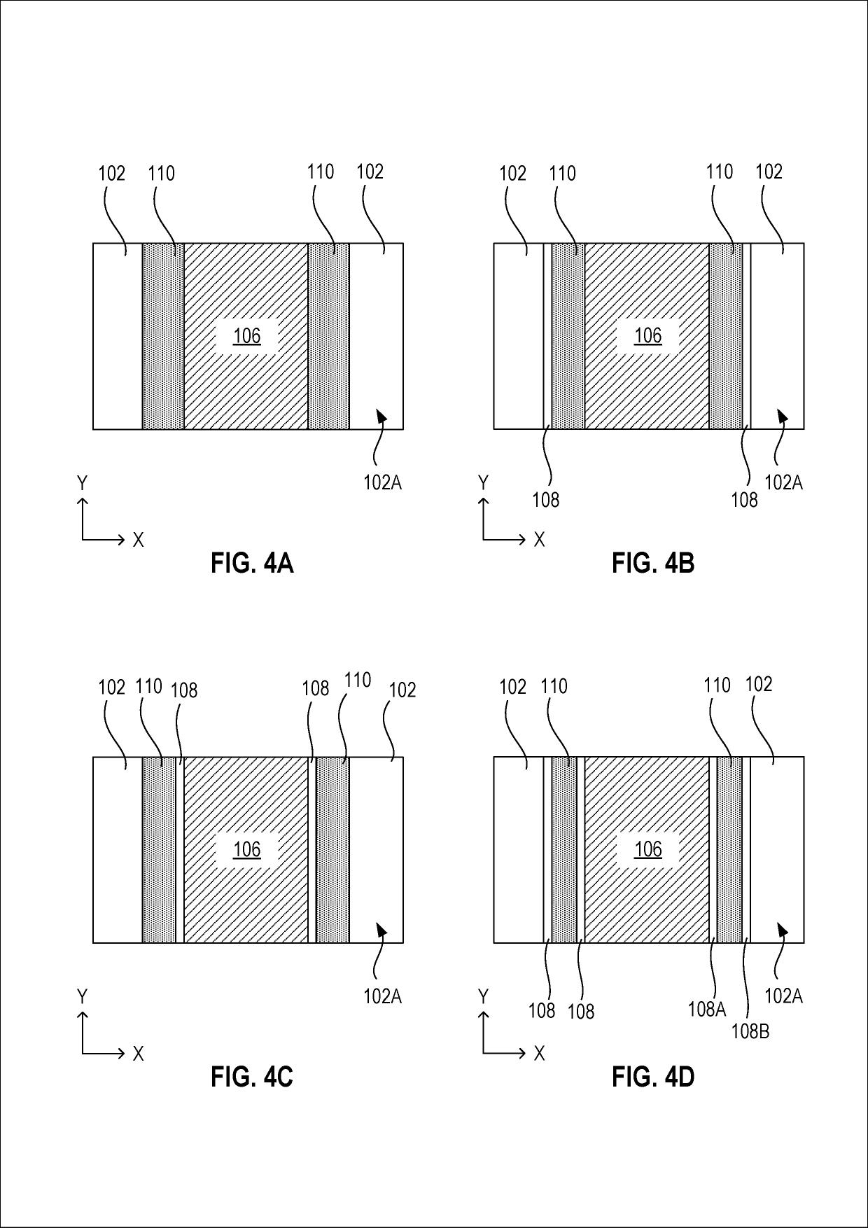

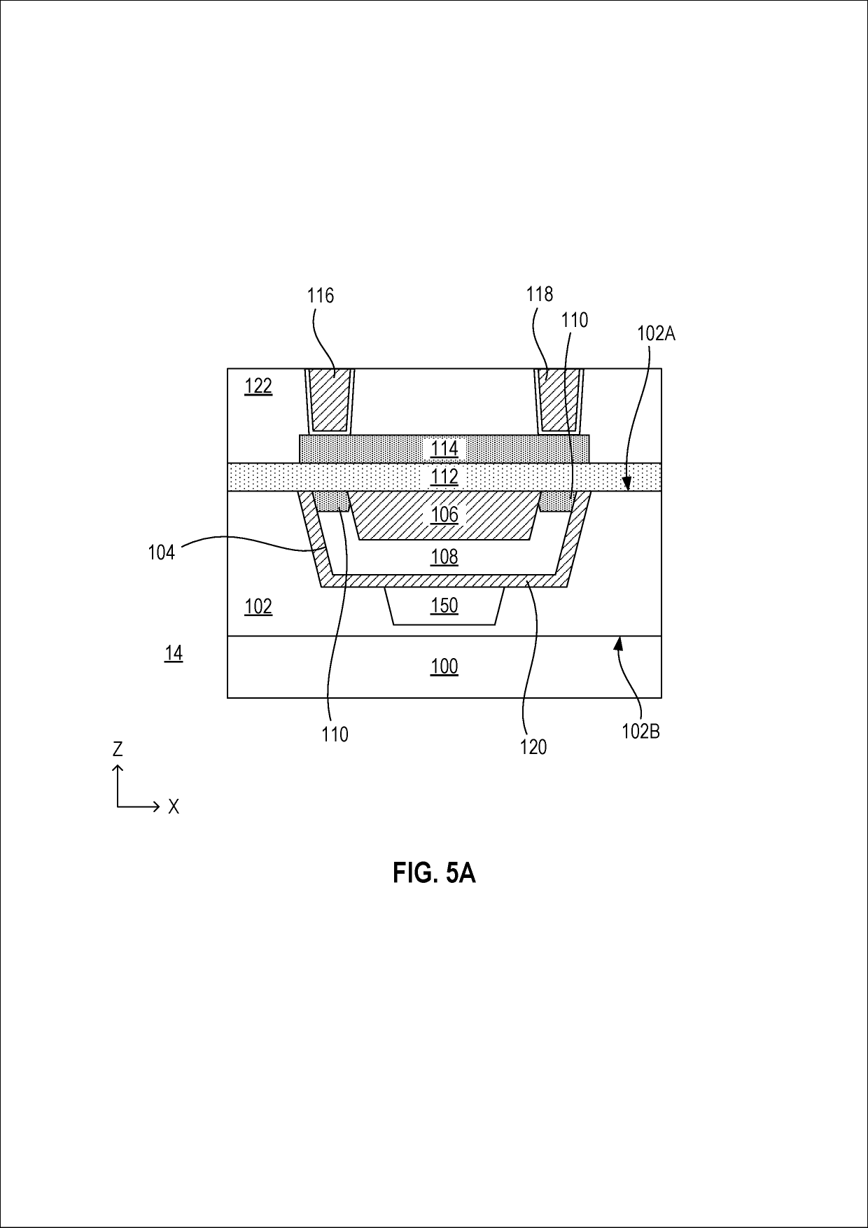

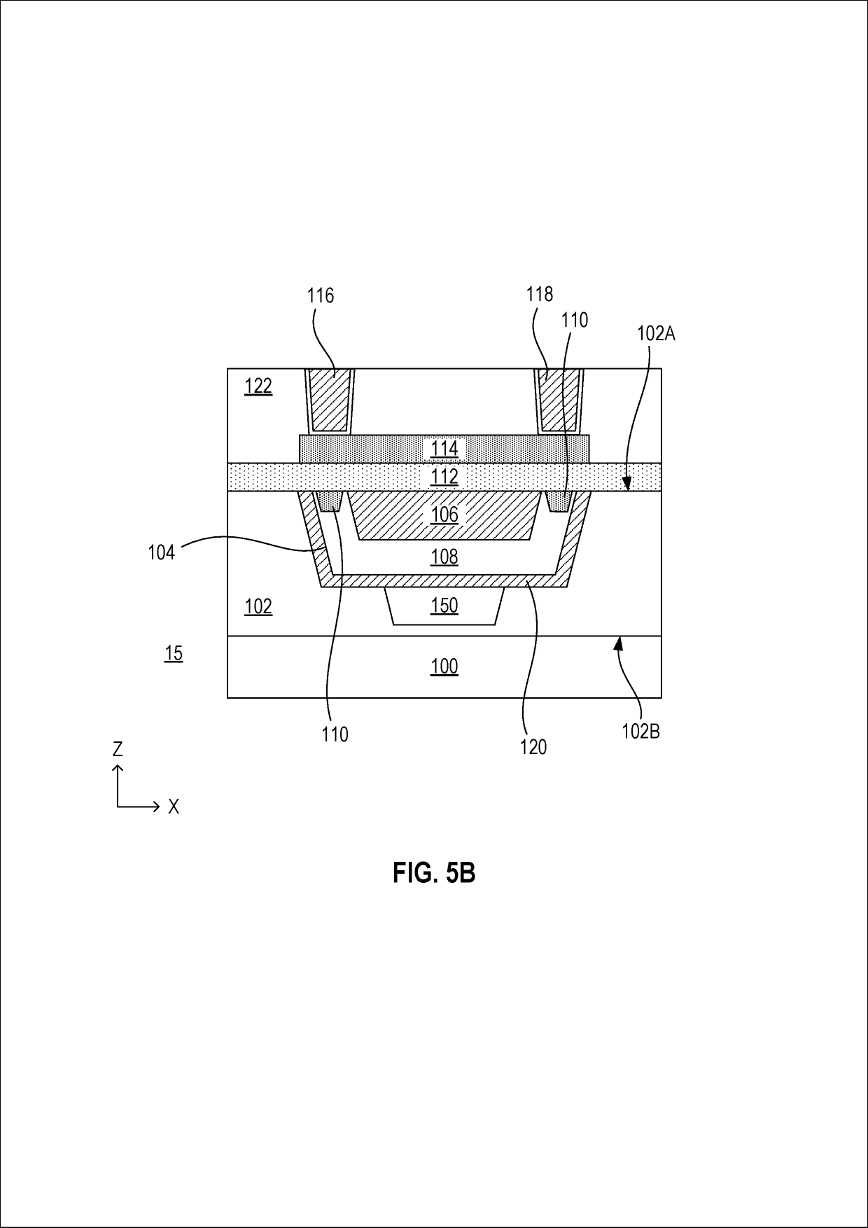

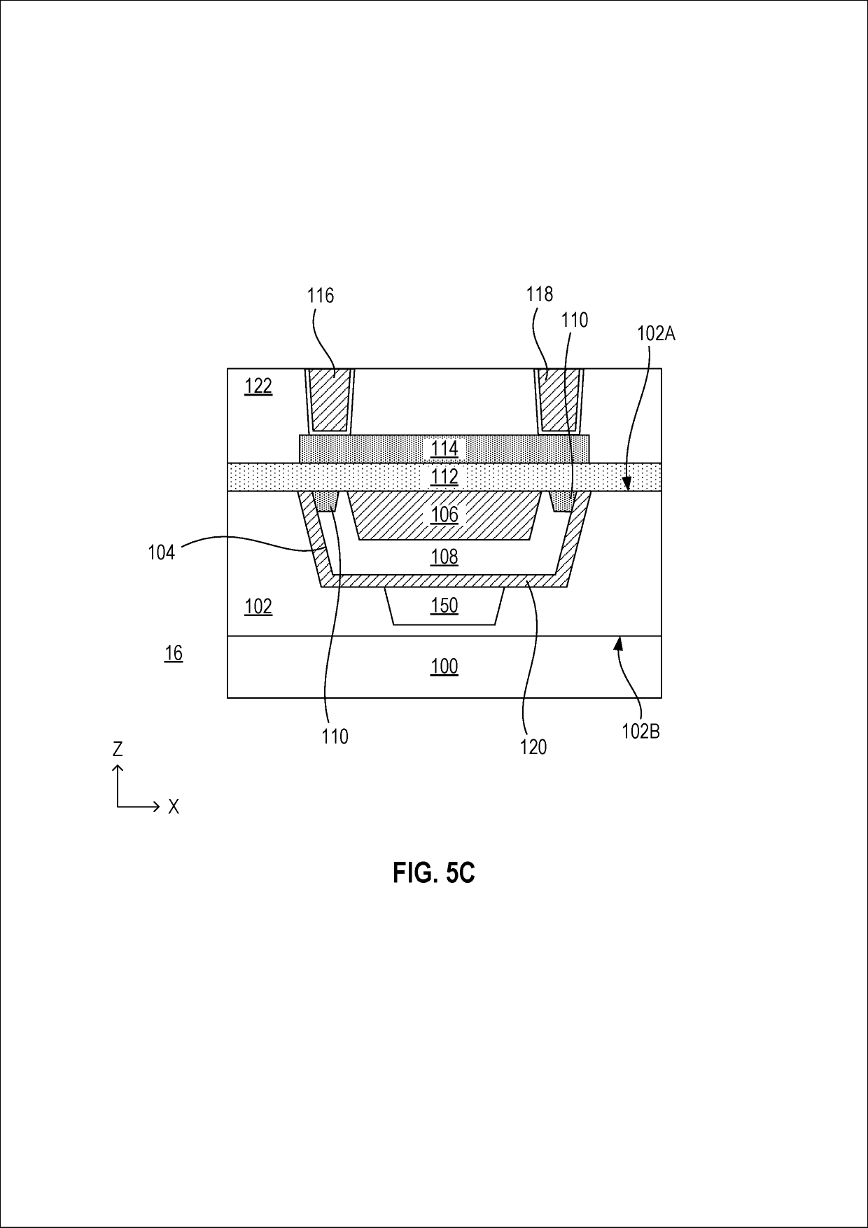

Referring to FIGS. 4A to 4D, which illustrate top views of the first side 102A of the insulating layer 102 according to some embodiments of the present disclosure. These figures shows a section of the gate material portion 106 along the y-axis as examples. In the scenario where the oxide portion 110 is embedded in the barrier layer 108, the barrier layer 108 may: (1) not be exposed at the two opposite (lateral) sides of the oxide portion 110 (e.g., FIG. 4A), (2) be exposed on one (lateral) side of the oxide portion 110 (e.g., FIGS. 4B or 4C), or (3) be exposed on both (lateral) sides of the oxide portion 110 (e.g., FIG. 4D). This variation depends on the width of the barrier layer 108, the width of the oxide portion 110, and/or the etching technique used to form the trench for the oxide portion 110. In some embodiments, as labeled in FIG. 4D, an inner portion 108A of the barrier layer 108 and an outer portion 108B of the barrier layer 108 is spaced by the oxide portion 110 at the first side 102A of the insulating layer 102.

Referring to the embodiments shown in FIGS. 1 to 3B, in some embodiments, a dielectric layer (e.g., a high-k dielectric layer 112) can disposed over the insulating layer 102. The high-k dielectric layer 112 can be a gate dielectric layer which is formed over the insulating layer 102 and the gate structure 104. In some embodiments, the high-k dielectric layer 112 may include high-k dielectric materials that with a dielectric constant greater than 3.9, or some other suitable dielectric materials. In some embodiments, the high-k dielectric layer 112 may include silicon oxide, silicon nitride, silicon oxynitride, hafnium oxide (HfO₂), hafnium silicon oxide (HfSiO), hafnium silicon oxynitride (HfSiON), hafnium silicate (HfOₓSi), hafnium tantalum oxide (HfTaO), hafnium titanium oxide (HfTiO), hafnium zirconium oxide (HfZrO), zirconium silicate (ZrSiOₓ), zirconium aluminate, zirconium oxide (ZrOₓ), titanium oxide, aluminum oxide (Al₂O₃), a hafnium dioxide-alumina (HfO₂-Al₂O₃) alloy, or combinations thereof. In some embodiments, the high-k dielectric layer 112 may be formed by any suitable method, such as chemical vapor deposition (CVD). In some embodiments, there are two or more gate structures 104 embedded at the first side 102A of the insulating layer 102, the high-k dielectric layer 112 may extend and/or span across two or more gate structures 104.

In some embodiments, the semiconductor structure may further include a channel layer 114 over the high-k dielectric layer 112. The channel layer 114 may include indium gallium zinc oxide (InGaZnO, IGZO), tungsten-doped indium oxide (InWO), indium zinc oxide (InZnO), indium tin oxide (InSnO), Zinc oxide (ZnO), gallium oxide (GaOₓ), indium oxide (InOₓ), aluminum zinc oxide (AZO), or combinations thereof. The channel layer 114 is configured to perform a conductive channel that selectively formed based on current or a voltage being applied to the gate structure 104. In some embodiments, the thickness of the channel layer 114 is included in a range of about 3 nm to about 15 nm to achieve a sufficiently high current while achieving sufficient gate control and a sufficiently low leakage current.

In some embodiments, the semiconductor structure may further include a source structure 116 and a drain structure 118 over the channel layer 114. In some embodiments, the source structure 116 and the drain structure 118 are over the oxide portion 110 of the gate structure 104. The source structure 116 and the drain structure 118 may be electrically coupled with channel layer 114 such that current is selectively permitted to flow between the source structure 116 and the drain structure 118 through the channel layer 114. The source structure 116 and the drain structure 118 may each include one or more semiconductor materials, such as silicon (Si), germanium (Ge), doped silicon, and/or doped germanium. In some embodiments, the material of the source structure 116 and the drain structure 118 may refer to the material of the gate material portion 106. That is, these electrodes may be made of metallic materials such as silver (Ag), aluminum (A1), copper (Cu), tungsten (W), nickel (Ni), other suitable metals, their alloys, or combinations thereof, or may include metal compounds such as titanium nitride (TiN), tantalum nitride (TaN), metal silicide, other suitable materials, or combinations thereof. These electrodes can also be a non-metal electrode composed of polycrystalline silicon. In some embodiments, the width W1 of the oxide portion 110 is substaintially equal to or less than a width W3 of the source structure 116 or the drain structure 118.

The equivalent capacitance (C_{eq}) of the capacitance of the high-k dielectric layer 112 (C_{HK}) and the capacitance of the channel layer 114 (C_{Channe}l) in the OFF state (C_{OFF}) can be calculated based on the formula that 1/C_{eq} = 1/C_{Channel} +1/C_{HK}, since the high-k dielectric layer 112 and the channel layer 114 connected in series in the aspect of capacitance. In some embodiments of the present disclosure, the oxide portion 110 is further connected to the high-k dielectric layer 112 and the channel layer 114 in series in the aspect of capacitance, the equivalent capacitance (C_{eq}) between the source/drain structures (116 and 118) and the gate structure 104 in the OFF state (C_{OFF}) can be calculated based on the formula that 1/C_{eq} = 1/C Channel +1/C_{HK} + 1/C_{OX}, wherein the capacitance of the oxide portion 110 (C_{OX}) is further added to reduce the equivalent capacitance (C eq). Therefore, by forming the oxide portion 110, the capacitance in the OFF state (C_{OFF}) can be reduced, and the subthreshold swing value (C_{OFF}/C_{ON}) of the semiconductor structure can be reduced accordingly.

In order to maximize the capacitance of the oxide portion 110 (C_{OX}) in the aspect of the position thereof, in some embodiments, the source structure 116 and the drain structure 118 are vertically aligned with the oxide portion 110 of the gate structure 104. In other words, in some embodiments of the present disclosure, there are several approaches can be implemented to gain more capacitance of the oxide portion 110 (C_{OX}) when the oxide portion 110 is formed in proximity to the sidewalls of the gate material portion 106, for instance, by increasing the thickness of the oxide portion 110 and/or forming the oxide portion 110 directly below the source structure 116 and the drain structure 118.

In addition to the reduce of the subthreshold swing value of the semiconductor structure by forming the oxide portion 110, meanwhile, the breakdown voltage (V BD) of the semiconductor structure can be increased since a thickness of the dielectric material is substantially increased by stacking the high-k dielectric layer 112 and the oxide portion 110, where the stack of the high-k dielectric layer 112 and the oxide portion 110 is in proximity to the physical breakdown point in the semiconductor structure.

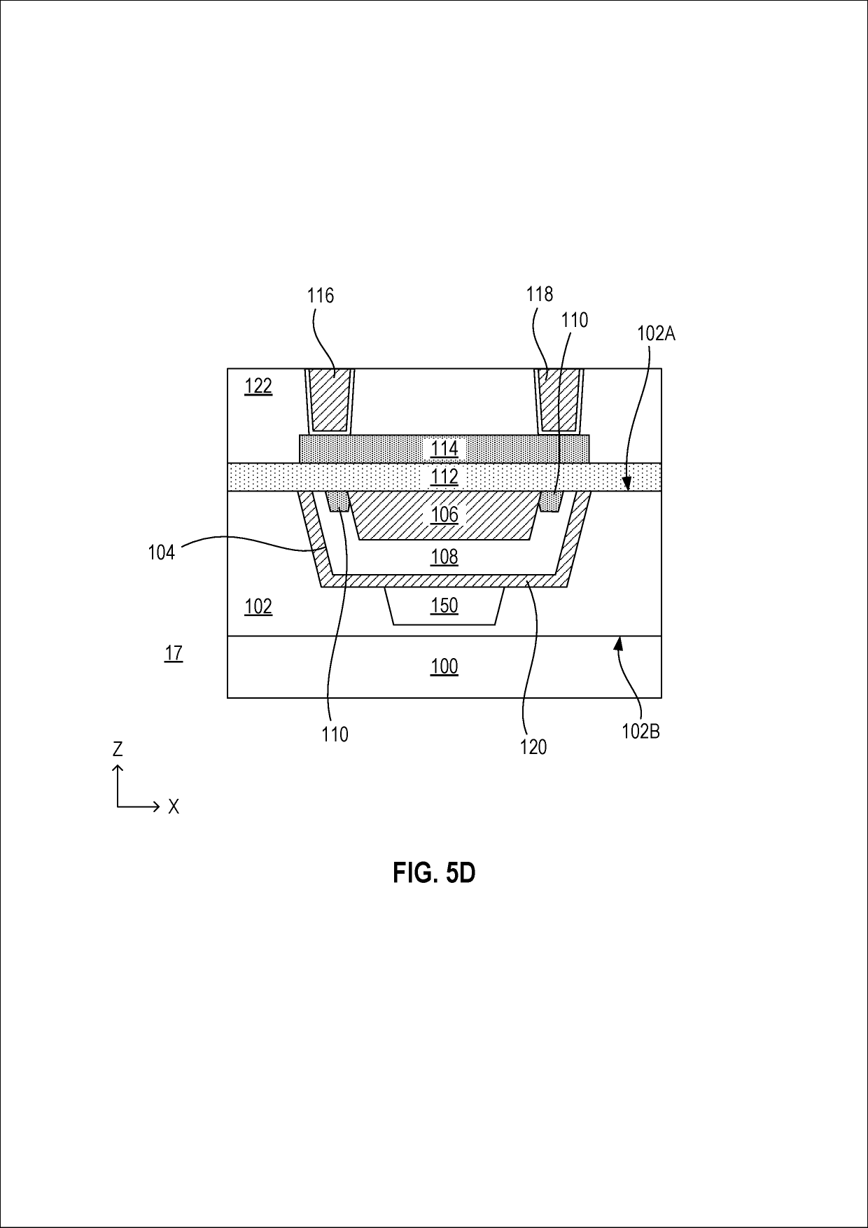

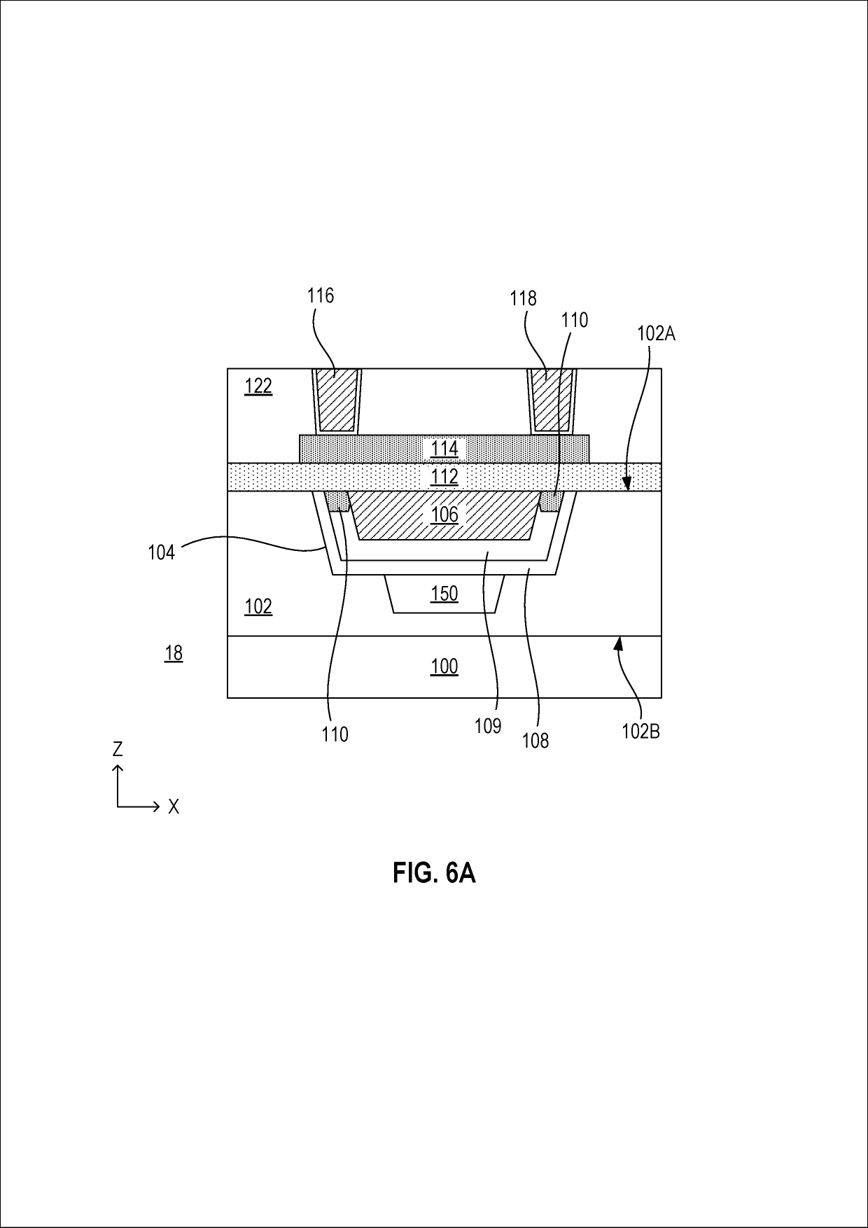

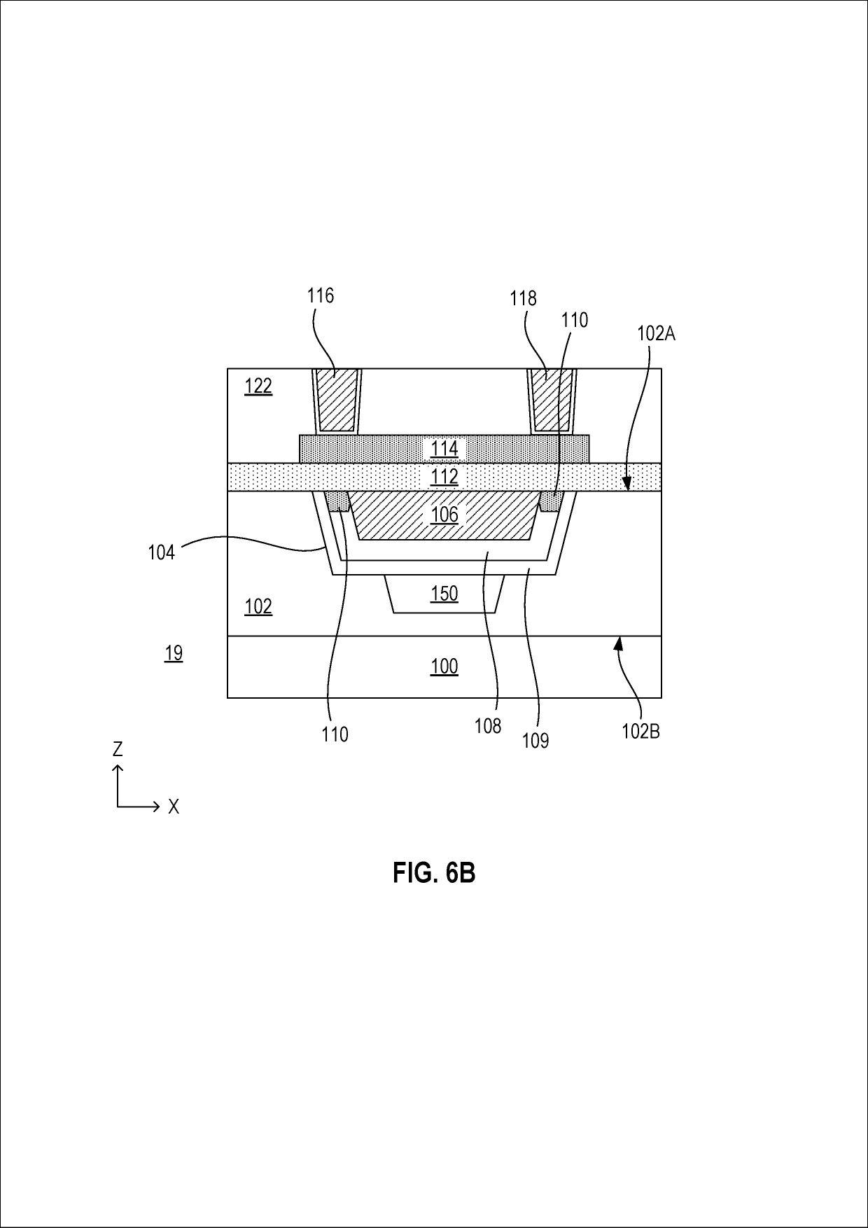

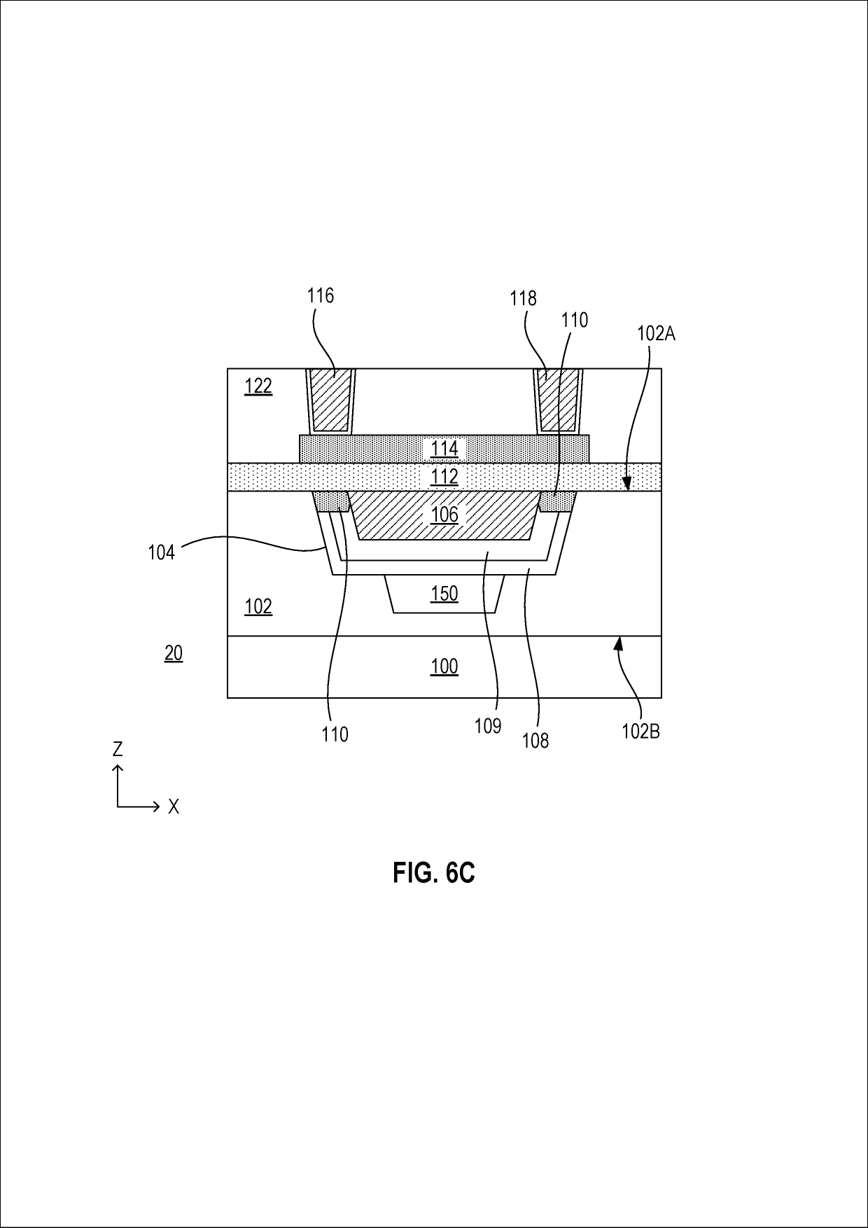

Referring to FIG. 5A, in some embodiments, a semiconductor structure 14 may include a metal barrier layer 120 in the insulating layer 102 and laterally surrounding the gate structure 104. In some embodiments, the metal barrier layer 120 is in contact with a sidewall of the barrier layer 108 and bottoms of the barrier layer 108 and the high-k dielectric layer 112. In some embodiments, a profile of the metal barrier layer 120 is at least conformal to the sidewall and the bottom of the barrier layer 108. In some embodiments, the metal barrier layer 120 can be a metal layer configured to reduce an interface resistance with a bottom metal, such as the conductive structure 150 below and/or under the gate structure 104 that previously described. In some embodiments, an upper surface of the metal barrier layer 120 is coplanar with the upper surface of the gate material portion 106 and an upper surface of the oxide portion 110.

FIG. 5A is an example that the oxide portion 110 is embedded in the barrier layer 108 at the first side 102A of the insulating layer 102. As previously shown in FIGS. 2 to 3B, the width of the barrier layer 108, the width of the oxide portion 110, and/or the etching technique used to form the trench for the oxide portion 110 may affect the profile of the barrier layer 108 after the oxide portion 110 is embedded therein, and FIGS. 5B to 5D is some examples (i.e., semiconductor structures 15, 16, and 17) that used to illustrate these variations in the scenario that the metal barrier layer 120 is formed in the insulating layer 102 and laterally surrounding the gate structure 104. As illustrated in FIGS. 5A and 5C, in some embodiments, the metal barrier layer 120 may in contact with the oxide portion 110.

Referring to FIG. 6A, 6B, and 6C, in alternative embodiments, the oxide portion 110 in semiconductor structures 18, 19, and 20, respectively, can be embedded in the liner layer 109 at the first side 102A of the insulating layer 102 instead of merely embedded in the barrier layer 108 or merely embedded in the barrier layer 108, depending on the material of the liner layer 109 (e.g., oxide semiconductor). In some embodiments, the positions of the barrier layer 108 and the liner layer 109 can be switched, such as the differences between the embodiments shown in FIGS. 6A and 6B. Accordingly, in some embodiments, the barrier layer 108 can be sandwiched by the liner layer 109 and the gate material portion 106 (see FIG. 6B), while the oxide portion 110 can embedded in the barrier layer 108, in the liner layer 109, or both. In these embodiments, the metal barrier layer 120 shown in FIGS. 5A to 5D can also be formed in the insulating layer 102 and laterally surrounding the gate structure 104.

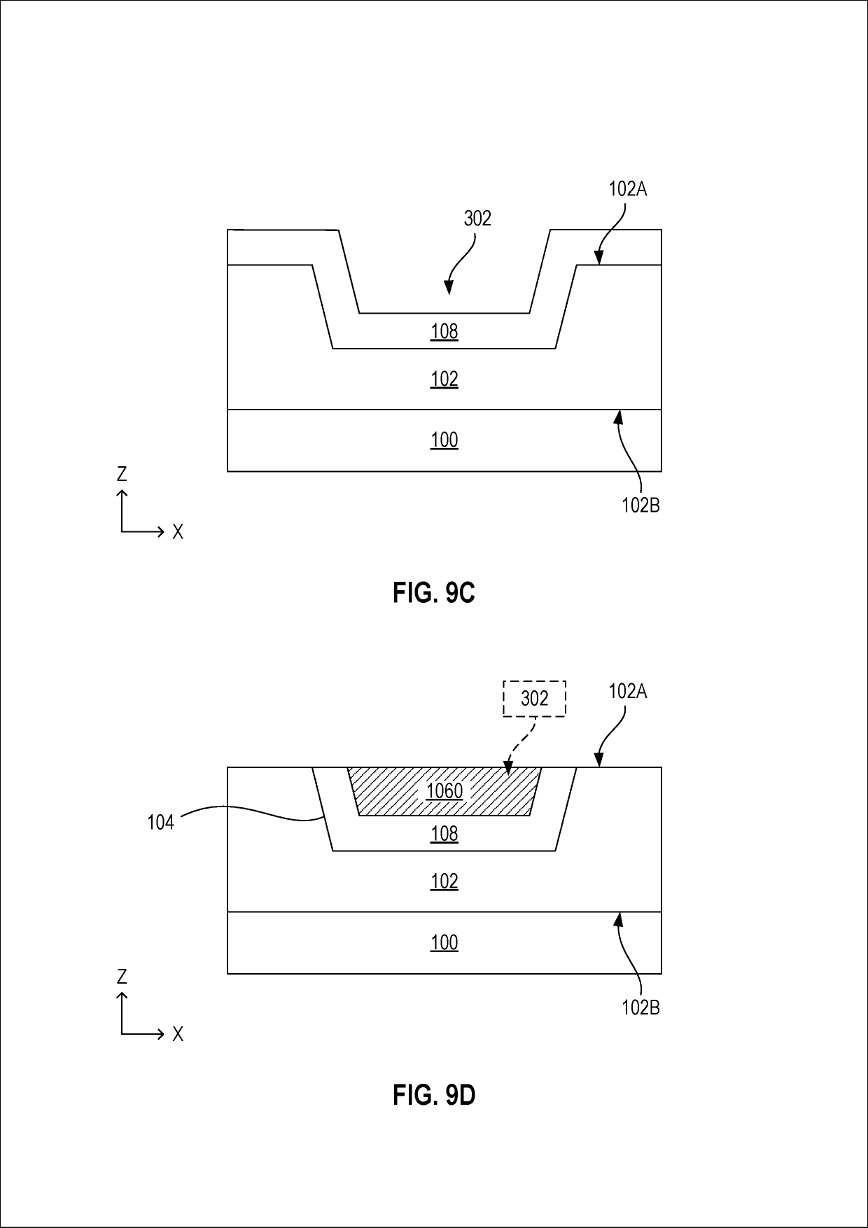

Referring to FIG. 7, in some embodiments, the source structure 116 and the drain structure 118 may be respectively electrically coupled with interconnect structures. For example, the source structure 116 and the drain structure 118 may be coupled with an interconnect structure 130 that is located over the source structure 116 and the drain structure 118. In some embodiments, the semiconductor structure disclosed in the present disclosure is a transistor structure for used in a memory structure (e.g., DRAM), while the interconnect structure 130 may further electrically coupled with a bit line conductive structure 132 and/or a column line conductive structure that over the interconnect structure 130. The bit line conductive structure 132 may be configured to selectively receive a current from a capacitor structure 134 or to provide a current to the capacitor structure 134 through the semiconductor structure there below (i.e., transistor structure).

Generally, the semiconductor structure disclosed in the present disclosure is a transistor structure applicable in a wide range of fields, such as a thin film transistor (TFT), different types of volatile memory cell structures, etc.

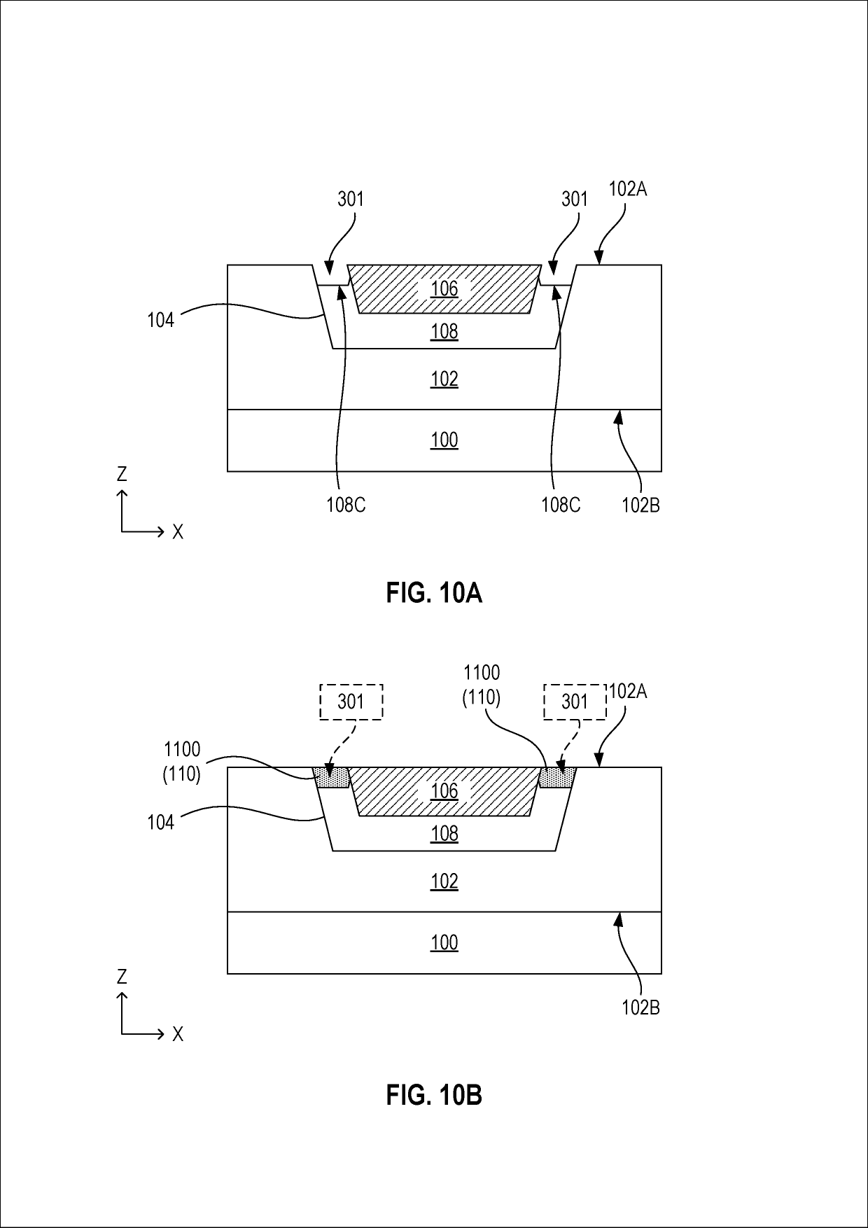

FIG. 8 is a flow diagram illustrating a method 200 for manufacturing a semiconductor structure according to some embodiments of the present disclosure. In some embodiments, the method includes: an operation 201: receiving a substrate having an insulating layer; an operation 202: forming a gate structure in the insulating layer,; an operation 203: forming a first trench at an upper side of the barrier layer of the gate structure; an operation 204: filling the first trench with an insulation material; an operation 205: forming a dielectric layer over the insulating layer; an operation 206: forming a channel layer over the dielectric layer; and an operation 207: forming a source structure and a drain structure over the channel layer. In some embodiments, the gate structure includes a gate material portion extending downward from the first side of the insulating layer and a barrier layer laterally surrounding the gate material portion.

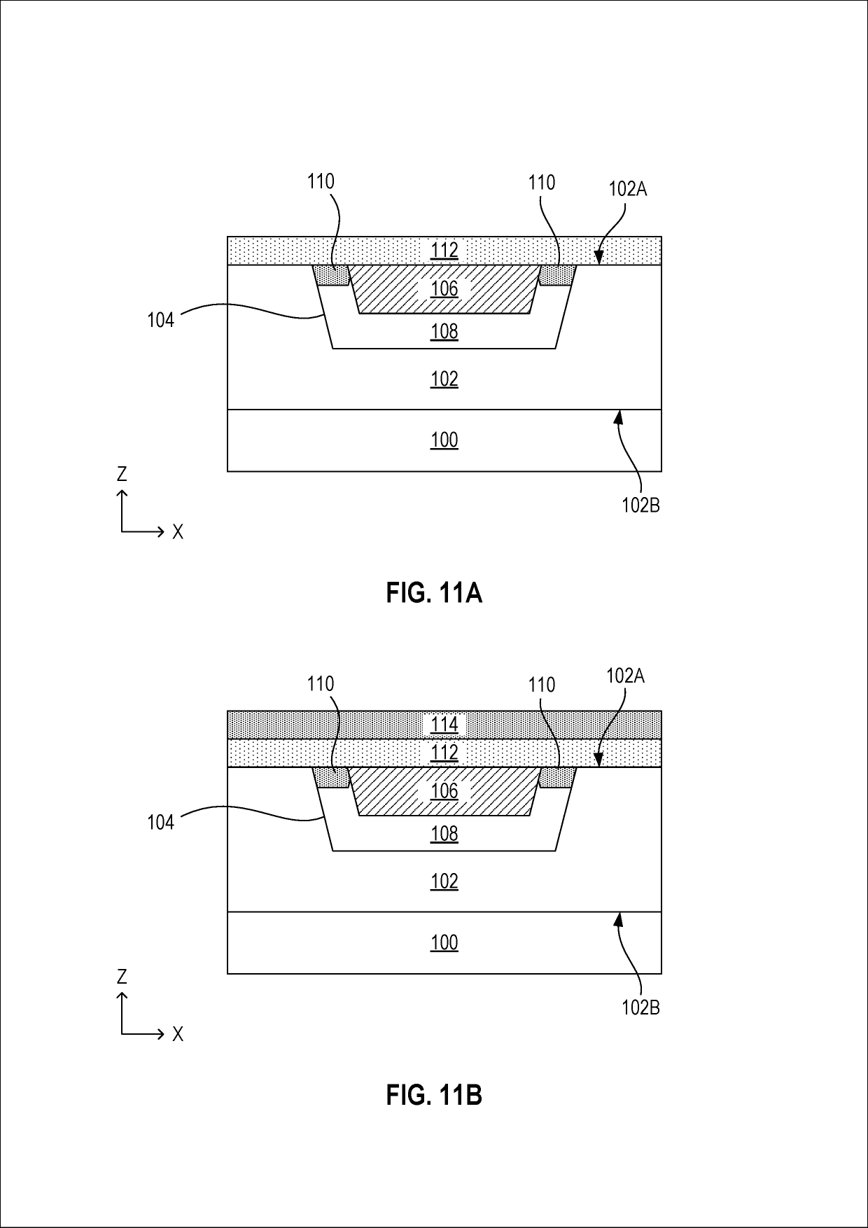

Referring to FIG. 9A, in some embodiments, the substrate 100 having the insulating layer 102 at the first side 102 of the substrate 100 is received. In some embodiments, the substrate 100 may include layers, structures, and/or components formed through a BEOL process and or a FEOL process. The insulation layer 102 may include a dielectric material such as silicon oxide, silicon nitride, silicon oxynitride, a spin-on dielectric material, or a low-k dielectric material (e.g., a material with a dielectric constant generally lower than about 3.9). Additionally, the insulation layer 102 may include undoped silicate glass, doped silicate glass, organosilicate glass, or a porous dielectric material. In some embodiments, the thickness of the insulation layer 102 may range from about 20 nm to about 300 nm.

To form the gate structure, referring to FIG. 9B, in some embodiments, a second trench 302 can be formed at an upper surface of the insulating layer 102 through a patterning/etching process. The upper surface can be the surface at the first side 102A of the insulating layer 102. Next, referring to FIG. 9C, the barrier layer 108 can be conformally formed in the second trench 302 through a blanket deposition process. In some embodiments, the barrier layer 108 is performed as a gate barrier and can be made of a metal oxide material. After forming the barrier layer 108, referring to FIG. 9D, a gate material 1060 is filled in the second trench 302 and over the barrier layer 108, to ensure that the gate material portion in the gate structure may extend downward from the first side 102A of the insulating layer 102 and the barrier layer 108 can laterally surround the gate material portion. Referring to FIG. 9D, a chemical mechanical planarization (CMP) operation can be performed to planarize the gate structure 104.

Generally, the deposition process in some embodiments of the present disclosure can be implemented by using a deposition tool that using a CVD technique, a physical vapor deposition (PVD) technique, an atomic layer deposition (ALD) technique, and other suitable deposition technique. The etching process can be implemented by using a plasma etch technique, a wet chemical etch technique, and/or another type of etch technique.

In alternative embodiments, before forming the gate structure, the metal barrier layer 120 (shown in FIGS. 5A-5D) can be formed in the second trench 302 through a blanket deposition process. In such embodiment, the barrier layer 108 is subsequently formed over the metal barrier layer 120.

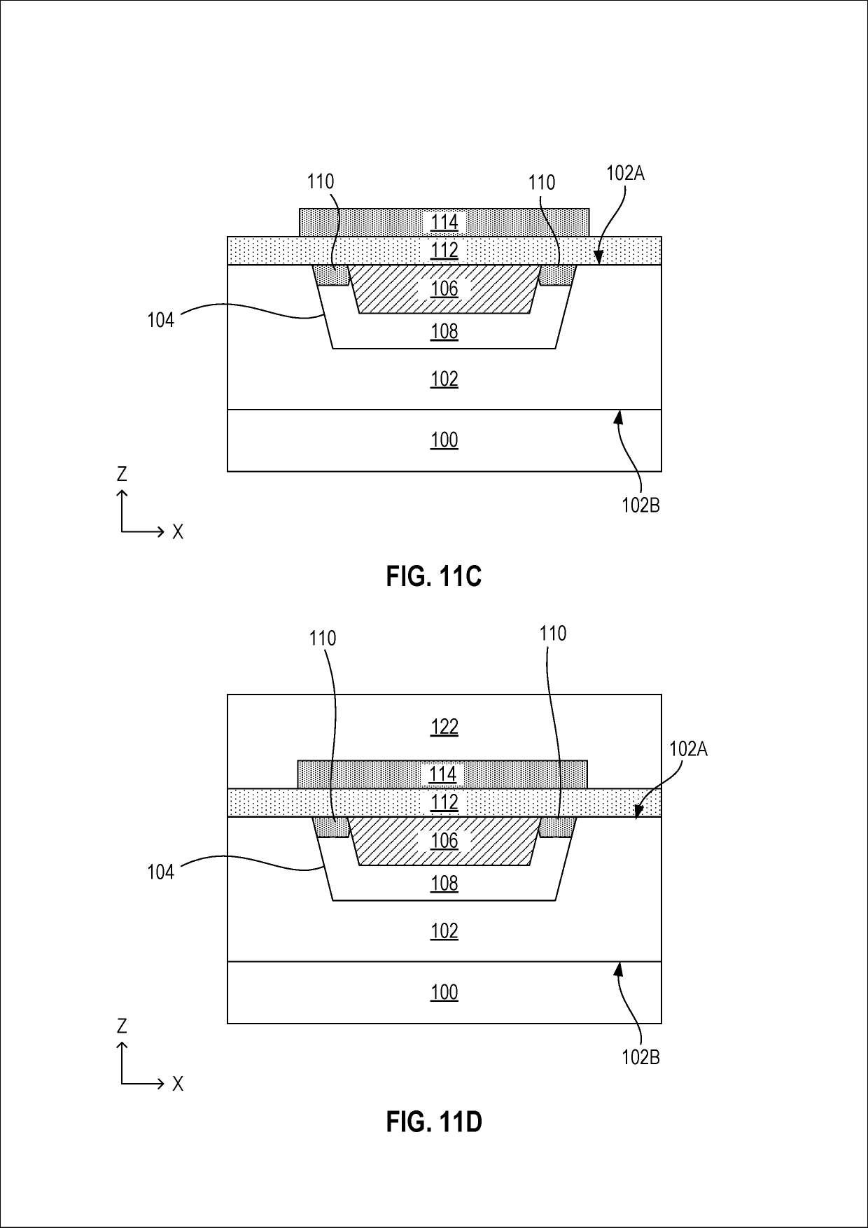

Referring to FIG. 10A, in some embodiments, a first trench 301 can be formed at an upper side 108C of the barrier layer 108 of the gate structure 104 through a patterning/etching process. In some embodiments, a width of the first trench 301 is in a range from about 10 nm to about 100 nm, depending on the width of the barrier layer 108. That is, in forming the first trench 301, a high selectivity etchant can be used to remove a portion of the barrier layer 108, and therefore the first trench 301 is substantially extended downward along the profile of the barrier layer 108. In some embodiments, a depth of the first trench 301 is in a range from about 0.5 nm to about 10 nm. In some embodiments, the depth of the first trench 301 is less than the thickness of the gate material portion 106.

Referring to FIG. 10B, in some embodiments, an insulation material such as an oxide material 1100 is filled in the first trench 301, to ensure that the oxide portion in the gate structure may extend downward from the first side 102A of the insulating layer 102 and be embedded in the barrier layer 108. In some embodiments, the oxide material 1100 includes SiO₂ or AlOₓ, or other dielectric material with low-k value. After filling the first trench 301 with the insulation material, a CMP operation can be performed to planarize the gate structure 104 to form the oxide portion 110.

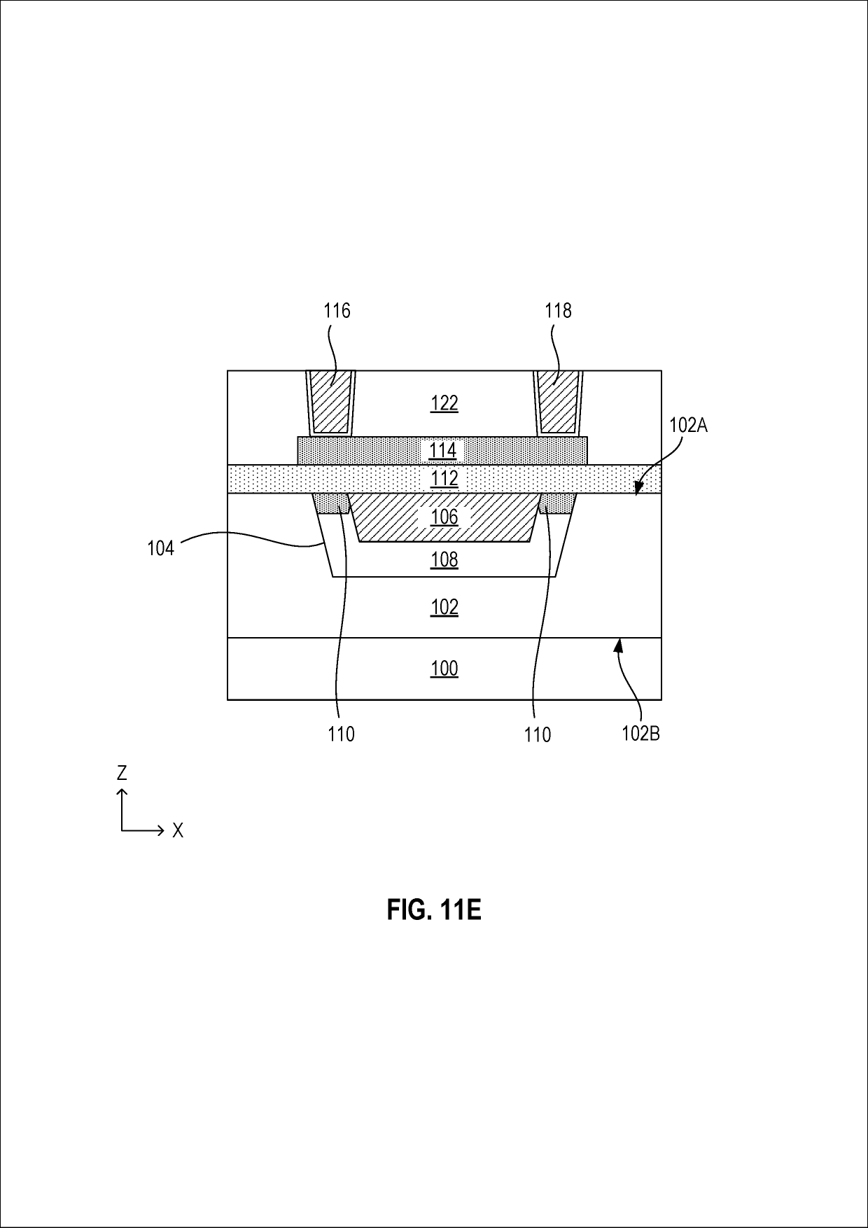

Referring to FIG. 11A, in some embodiments, the high-k dielectric layer 112 is formed over the gate structure 104 through a blanket deposition process. In some embodiments, the high-k dielectric layer 112 may include high-k dielectric materials that with a dielectric constant greater than 3.9, or some other suitable dielectric materials. Referring to FIG. 11B, in some embodiments, the channel layer 114 is formed over the dielectric layer 112 through a blanket deposition process. In some embodiments, the channel layer 114 may include indium gallium zinc oxide (InGaZnO, IGZO), tungsten-doped indium oxide (InWO), indium zinc oxide (InZnO), indium tin oxide (InSnO), Zinc oxide(ZnO), gallium oxide (GaOₓ), indium oxide (InOₓ), aluminum zinc oxide (AZO), or combinations thereof.

Referring to FIG. 11C, in some embodiments, the channel layer 114 can be patterned to be aligned with the size of the gate structure 104 located below. In some embodiments, the width of the channel layer 114 can in a range of about 30 nm to about 300 nm, depending on the size of the gate structure 104.

Referring to FIG. 11D, in some embodiments, a dielectric layer 122 can be formed over the dielectric layer 112 and the channel layer 114 through a blanket deposition process. Next, referring to FIG. 11E, in some embodiments, the source structure 116 and the drain structure 118 can be formed over the channel layer 114. In some embodiments, the source structure 116 and the drain structure 118 are vertically aligned with the oxide portion 110 of the gate structure 104. In some embodiments, the first trench 301 filled with the oxide material 1100 (see FIG. 10B) is projecteively below the source structure 116 and the drain structure 118. For example, as the cross-sectional view perspective shown in FIG. 11E, the source structure 116 and the drain structure 118 are directly over a first oxide portion 110A and a second oxide portion 110B of the gate structure, respectively. In some embodiments, as previously shown in FIG. 7, a plurality of with interconnect structures can be formed in or over the dielectric layer 122 to be electrically coupled with the source structure 116 and the drain structure 118.

Some embodiments of the present disclosure provide a semiconductor structure that an oxide portion is formed in a bottom gate structure. The oxide portion may provide a capacitance that may at least reduce the equivalent capacitance (e.g. C_{OFF}) between the S/D structure and the bottom gate structure since the oxide portion in the bottom gate structure are connected to the high-k dielectric layer and the channel layer in series in the aspect of capacitance. By reducing the equivalent capacitance, the semiconductor structure may have a low subthreshold swing (SS) value and the electrical performance thereof can be enhanced accordingly.

In one exemplary aspect, a semiconductor structure is provided. The semiconductor structure includes an insulating layer, a gate structure, a dielectric layer, a channel layer, and a source structure and/or a drain structure. The insulating layer has a first side and a second side opposite to the first side. The gate structure is embedded at the first side of the insulating layer. The dielectric layer is over the insulating layer and the gate structure. The channel layer is over the dielectric layer. The gate structure includes a gate material portion extending downward from the first side of the insulating layer; a barrier layer laterally surrounding the gate material portion; and an oxide portion embedded in the barrier layer at the first side of the insulating layer. The source structure or the drain structure is over the oxide portion of the gate structure.

In another exemplary aspect, a semiconductor structure is provided. The semiconductor structure includes an insulating layer, a gate structure, a dielectric layer, a channel layer, a source structure, and a drain structure. The gate structure is embedded in the insulating layer. The gate structure includes a gate material portion having two opposite sides and a first oxide portion and a second oxide portion adjacent to the gate material portion at the two opposite sides of the gate material portion. The dielectric layer is over the insulating layer. The channel layer is over the dielectric layer. The source structure and the drain structure are directly over the first oxide portion and the second oxide portion of the gate structure, respectively.

In yet another exemplary aspect, a method for manufacturing a semiconductor structure is provided. The method includes the operations as follows. A substrate having an insulating layer is received. A gate structure is formed in the insulating layer. The gate structure includes a gate material portion extending downward from a side of the insulating layer and a barrier layer laterally surrounding the gate material portion. A first trench is formed at an upper side of the barrier layer of the gate structure. The first trench is filled with an insulation material. A dielectric layer is formed over the insulating layer. A channel layer is formed over the dielectric layer. A source structure or a drain structure is formed over the channel layer.

The foregoing outlines structures of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
an insulating layer having a first side and a second side opposite to the first side;
a gate structure embedded at the first side of the insulating layer, the gate structure comprises:
a gate material portion extending downward from the first side of the insulating layer;
a barrier layer laterally surrounding the gate material portion; and
an oxide portion embedded in the barrier layer at the first side of the insulating layer;
a dielectric layer over the insulating layer and the gate structure;
a channel layer over the dielectric layer; and
a source structure and a drain structure over the oxide portion of the gate structure.

2. The semiconductor structure of claim 1, wherein the source structure and the drain structure are vertically aligned with the oxide portion of the gate structure.

3. The semiconductor structure of claim 1, wherein an upper surface of the oxide portion in the gate structure is coplanar with an upper surface of the gate material portion.

4. The semiconductor structure of claim 3, wherein a top surface of the barrier layer is substantially lower than the upper surface of the gate material portion.

5. The semiconductor structure of claim 1, further comprising a metal barrier layer in the insulating layer and laterally surrounding the gate structure.

6. The semiconductor structure of claim 5, wherein an upper surface of the metal barrier layer is coplanar with an upper surface of the gate material portion.

7. The semiconductor structure of claim 1, wherein a thickness of the oxide portion is less than a thickness of the gate material portion.

8. The semiconductor structure of claim 1, wherein an inner portion of the barrier layer and an outer portion of the barrier layer is spaced by the oxide portion of the gate structure.

9. The semiconductor structure of claim 1, wherein a thickness of the oxide portion of the gate structure is in a range from about 0.5 nm to about 10 nm.

10. A semiconductor structure, comprising:
an insulating layer;
a gate structure embedded in the insulating layer, the gate structure comprises:
a gate material portion having two opposite sides; and
a first oxide portion and a second oxide portion adjacent to the gate material portion at the two opposite sides of the gate material portion;
a dielectric layer over the insulating layer;
a channel layer over the dielectric layer; and
a source structure and a drain structure directly over the first oxide portion and the second oxide portion of the gate structure, respectively.

11. The semiconductor structure of claim 10, wherein a lower sidewall and a bottom of the gate material portion is in contact with a barrier layer.

12. The semiconductor structure of claim 11, wherein the first oxide portion and the second oxide portion are embedded in the barrier layer.

13. The semiconductor structure of claim 10, wherein a width of the first oxide portion is substantially equal to or less than a width of the source structure.

14. The semiconductor structure of claim 10, wherein the gate structure further comprises a liner layer laterally surrounding the gate material portion, and the first oxide portion and the second oxide portion are embedded in the liner layer.

15. The semiconductor structure of claim 14, wherein the gate structure further comprises a barrier layer laterally surrounding the gate material portion, and the liner layer is sandwiched by the gate material portion and the barrier layer.

16. A method for manufacturing a semiconductor structure, the method comprising:
receiving a substrate having an insulating layer;
forming a gate structure in the insulating layer, wherein the gate structure comprises a gate material portion extending downward from a side of the insulating layer and a barrier layer laterally surrounding the gate material portion;
forming a first trench at an upper side of the barrier layer of the gate structure;
filling the first trench with an insulation material;
forming a dielectric layer over the insulating layer;
forming a channel layer over the dielectric layer; and
forming a source structure and a drain structure over the channel layer.

17. The method of claim 16, wherein a depth of the first trench is less than a thickness of the gate material portion.

18. The method of claim 16, wherein the oxide material comprises SiO₂ or AlOₓ and a material of the barrier layer comprises InGaZnO, InWO, InZnO, InSnO, ZnO, GaOₓ InOₓ AZO, or combinations thereof.

19. The method of claim 16, further comprising:
forming a second trench at the side of the insulating layer before forming the gate structure in the insulating layer; and
forming a metal barrier layer in the second trench.

20. The method of claim 16, wherein the first trench filled with the oxide material is projecteively below the source structure and the drain structure.
